(19) United States
(12) Patent Application Publication
(10) Pub. No.: US 2025/0344403 A1
(43) Pub. Date: Nov. 6, 2025

(54) SPIN DEVICE

(71) Applicant: Nippon Telegraph and Telephone Corporation, Chiyoda-ku (JP)

(72) Inventors: Rento Osugi, Tokyo (JP); Katsuhiko Nishiguchi, Tokyo (JP)

(21) Appl. No.: 18/865,828

(22) PCT Filed: Jul. 19, 2022
(86) PCT No.: PCT/JP2022/027986

§ 371 Date: Nov. 14, 2024

(51) Int. Cl. H10B 61/00

(52) U.S. Cl. CPC H10B 61/22

(57) ABSTRACT

This spintronic device includes a semiconductor layer formed on a substrate, a source and a drain formed in the semiconductor layer at a predetermined interval, and a channel formed between the source and the drain in the semiconductor layer. The channel is a region in the semiconductor layer doped with a magnetic impurity. The spintronic device also includes a gate that is formed of a ferroelectric substance and applies an electric field to the channel.

### CROSS-REFERENCE TO RELATED APPLICATIONS

This application is a national phase entry of PCT Application No. PCT/JP2022/027986, filed on Jul. 19, 2022, which application is hereby incorporated herein by reference.

### TECHNICAL FIELD

The present invention relates to a spintronic device.

### BACKGROUND

Semiconductor spintronics, the field that utilizes carrier spins in a semiconductor, has been attracting attention. For example, next-generation spintronic devices such as spin memories and quantum computers have been developed. These spintronic devices are obtained by newly adding a spin degree of freedom to semiconductors in the related art. In one instance, a technique for electrically controlling magnetization has been attracting attention as the operating principle of a new electronic device and has been proposed to utilize in a device of a nonvolatile logic circuit such as a power-saving multi-valued memory. As basic technology for this proposal, multiferroic materials and ferromagnetic semiconductors have been developed (Patent Literature 1, Non Patent Literature 1).

For example, a multiferroic material is a system that combines ferroelectricity and ferromagnetism and has a magnetization direction that changes depending on a polarization direction. In a multiferroic material, since a polarization direction is controllable by an electric field and is retained in a state where the electric field is turned off, it is possible to control an electromagnetic field in a magnetization direction. In other words, an electric field enables a device to compute and record a plurality of information media (polarization and magnetization). These characteristics of a multiferroic material are derived from a crystal structure and its orientation in a multicomponent material that has precisely controlled compositions, which requires an advanced production technique.

Multiferroic materials, however, have the following problems. Molecular beam epitaxy (MBE) and metal-organic chemical vapor deposition (MOCVD) have been employed as methods for producing a multiferroic material. In order to grow crystals by MBE, there are limitations to the precise composition control of a plurality of elements and the type of a base layer adequate for forming a crystal structure. A compositional deviation or an inadequate base layer causes a heterogeneous phase or deterioration in orientation, which nullifies the effect of the material. Even MOCVD, which is practical for large-area device production, has a problem in device production in addition to the problem similar to MBE. That is, a discontinuous film is formed by non-uniform crystal growth.

A ferromagnetic semiconductor is a system that combines semiconductivity and ferromagnetism and is a material capable of generating or eliminating a ferromagnetic state (magnetization) by inducing or preventing charges by an electric field. Such characteristics impart any semiconductor device in the related art with the capability of a magnetic body to control an electric field.

### CITATION LIST

### Patent Literature

Patent Literature 1: U.S. Pat. No. 8,860,006

### Non Patent Literature

Non Patent Literature 1: S. Ikeda et al., “Magnetic Tunnel Junctions for Spintronic Memories and Beyond”, IEEE Transactions on Electron Devices, vol. 54, no. 5, pp. 991-1002, 2007.

### SUMMARY

### Technical Problem

As described above, a ferromagnetic semiconductor shows promise as a material for a next-generation spintronic device, but a new spintronic device that uses a ferromagnetic semiconductor has not been proposed.

The present invention has been made to solve the problem, and an object of the present invention is to provide a new spintronic device that uses a ferromagnetic semiconductor.

### Solution to Problem

A spintronic device according to embodiments of the present invention includes a semiconductor layer formed on a substrate, a source and a drain formed in the semiconductor layer at a predetermined interval, a channel formed between the source and the drain in the semiconductor layer and doped with a magnetic impurity, and a first ferroelectric layer and a second ferroelectric layer that are formed of a ferroelectric substance and apply an electric field to both ends of the channel in a direction from the source to the drain to deplete the both ends of the channel.

A spintronic device according to embodiments of the present invention includes a semiconductor layer formed on a substrate, a source and a drain formed in the semiconductor layer at a predetermined interval, and a channel formed between the source and the drain in the semiconductor layer and doped with a magnetic impurity, and a gate that is formed of a ferroelectric substance and applies an electric field to the channel.

### Advantageous Effects

As described above, according to embodiments of the present invention, since the ferroelectric layers are disposed on the channel formed by adding the magnetic impurity between the source and the drain in the semiconductor layer, there is provided a new spintronic device that uses a ferromagnetic semiconductor.

### BRIEF DESCRIPTION OF THE DRAWINGS

FIG. 1 is a cross-sectional view illustrating a configuration of a spintronic device according to a first embodiment of the present invention.

FIG. 2 is a cross-sectional view illustrating a configuration of a spintronic device according to a second embodiment of the present invention.

FIG. 3 is a cross-sectional view illustrating a configuration of a spintronic device according to a third embodiment of the present invention.

FIG. 4A is a view for describing charge spins and spontaneous magnetization generated by interactions between charges and impurity ions in a semiconductor doped with a magnetic impurity.

FIG. 4B is a view for describing control of a ferromagnetic state and a non-magnetic state by injecting and ejecting charges from a source 203 into a channel 205.

FIG. 4C is a view for describing a state where a potential of a semiconductor channel immediately below a first ferroelectric layer 206a and a second ferroelectric layer 206b increases due to spontaneous polarization of the first ferroelectric layer 206a and the second ferroelectric layer 206b and the charges injected into the channel 205 are trapped.

FIG. 4D is a characteristic diagram illustrating potentials of the entire device when the charges injected into the channel 205 are trapped.

FIG. 5A is a cross-sectional view for describing a method for manufacturing the spintronic device according to the third embodiment of the present invention, illustrating a state of the spintronic device in process.

FIG. 5B is a cross-sectional view for describing the method for manufacturing the spintronic device according to the third embodiment of the present invention, illustrating a state of the spintronic device in process.

FIG. 5C is a plan view for describing the method for manufacturing the spintronic device according to the third embodiment of the present invention, illustrating a state of the spintronic device in process.

FIG. 5D is a cross-sectional view for describing the method for manufacturing the spintronic device according to the third embodiment of the present invention, illustrating a state of the spintronic device in process.

FIG. 5E is a cross-sectional view for describing the method for manufacturing the spintronic device according to the third embodiment of the present invention, illustrating a state of the spintronic device in process.

FIG. 5F is a cross-sectional view for describing the method for manufacturing the spintronic device according to the third embodiment of the present invention, illustrating a state of the spintronic device in process.

FIG. 5G is a cross-sectional view for describing the method for manufacturing the spintronic device according to the third embodiment of the present invention, illustrating a state of the spintronic device in process.

FIG. 5H is a plan view for describing the method for manufacturing the spintronic device according to the third embodiment of the present invention, illustrating a state of the spintronic device in process.

FIG. 5I is a plan view for describing the method for manufacturing the spintronic device according to the third embodiment of the present invention, illustrating a state of the spintronic device in process.

FIG. 5J is a plan view for describing the method for manufacturing the spintronic device according to the third embodiment of the present invention, illustrating a state of the spintronic device in process.

FIG. 5K is a cross-sectional view for describing the method for manufacturing the spintronic device according to the third embodiment of the present invention, illustrating a state of the spintronic device in process.

FIG. 5L is a cross-sectional view for describing the method for manufacturing the spintronic device according to the third embodiment of the present invention, illustrating a state of the spintronic device in process.

FIG. 5M is a cross-sectional view for describing the method for manufacturing the spintronic device according to the third embodiment of the present invention, illustrating a state of the spintronic device in process.

FIG. 5N is a cross-sectional view for describing the method for manufacturing the spintronic device according to the third embodiment of the present invention, illustrating a state of the spintronic device in process.

FIG. 5O is a cross-sectional view for describing the method for manufacturing the spintronic device according to the third embodiment of the present invention, illustrating a state of the spintronic device in process.

FIG. 5P is a cross-sectional view for describing the method for manufacturing the spintronic device according to the third embodiment of the present invention, illustrating a state of the spintronic device in process.

FIG. 5Q is a cross-sectional view for describing the method for manufacturing the spintronic device according to the third embodiment of the present invention, illustrating a state of the spintronic device in process.

FIG. 5R is a cross-sectional view for describing the method for manufacturing the spintronic device according to the third embodiment of the present invention, illustrating a state of the spintronic device in process.

FIG. 5S is a cross-sectional view for describing the method for manufacturing the spintronic device according to the third embodiment of the present invention, illustrating a state of the spintronic device in process.

FIG. 6A is a view for describing an operation of the spintronic device according to the third embodiment as a nonvolatile multi-valued memory.

FIG. 6B is a view for describing an operation of the spintronic device according to the third embodiment as a nonvolatile multi-valued memory.

FIG. 7 is a characteristic diagram illustrating current characteristics of the channel 205.

FIG. 8 shows (a) an equivalent circuit diagram illustrating the channel 205 and a control line 209 being electrostatically coupled by stray capacitance and (b) a characteristic diagram illustrating a state of a current flowing through the control line 209.

FIG. 9 is a view illustrating an operational state of a multi-valued memory in which a plurality of states in a current I(CH) of the channel 205 is retained even when inputs to the first ferroelectric layer 206a and the second ferroelectric layer 206b are blocked.

FIG. 10A is a view for describing an electronic state in the channel 205 when the channel 205 has a nanoscale dimension and the first ferroelectric layer 206a and the second ferroelectric layer 206b have a nanoscale interval therebetween.

FIG. 10B is a view for describing an electronic state in the channel 205 when the channel 205 has a nanoscale dimension and the first ferroelectric layer 206a and the second ferroelectric layer 206b have a nanoscale interval therebetween.

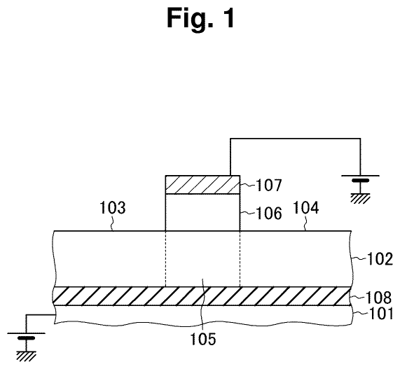

FIG. 1i shows (a) a plan view illustrating a plurality of spintronic devices connected in a lattice pattern and (b) a characteristic diagram illustrating a magnetization state of adjacent channels 205.

### DETAILED DESCRIPTION OF ILLUSTRATIVE EMBODIMENTS

Hereinafter, a spintronic device according to an embodiment of the present invention will be described.

### First Embodiment

First, a spintronic device according to a first embodiment of the present invention will be described with reference to FIG. 1. This spintronic device includes a semiconductor layer 102 formed on a substrate 101, a source 103 and a drain 104 formed in the semiconductor layer 102 at a predetermined interval, and a channel 105 formed between the source 103 and the drain 104 in the semiconductor layer 102. The channel 105 is a region in the semiconductor layer 102 doped with a magnetic impurity. The spintronic device also includes a gate 106 that is formed of a ferroelectric substance and applies an electric field to the channel 105. On the gate 106, a metallic electrode 107 is formed.

The substrate 101 is, for example, a silicon substrate. In this case, the semiconductor layer 102 is formed on the substrate 1i with an insulating layer 108 involved. The semiconductor layer 102 is formed of, for example, silicon. Examples of the magnetic impurity added to the semiconductor layer 102 in the region of the channel 105 includes Fe, Co, and Mn. The channel 105 doped with the magnetic impurity becomes a ferromagnetic semiconductor. The gate 106 is formed of, for example, HfO2.

For example, applying a positive voltage between the source 103 and the drain 104 enables injection of charges into the channel 105. In addition, adjusting a potential of the channel 105 by a voltage applied between the gate 106 and the substrate 101 enables induction of the charges in the channel 105.

Furthermore, applying a positive voltage between the source 103 and the drain 104 and adjusting a potential of the channel 105 by a voltage applied between the gate 106 and the substrate 101 enable ejection of the charges from the channel 105 to the drain 104. Still further, adjusting a potential of the channel 105 by a voltage applied between the gate 106 and the substrate 101 enables elimination of the charges in the channel 105.

In the channel 105 where charges exist, interactions between the charges and impurity generates spontaneous magnetization in a direction opposite to charge spins. As described above, controlling the injection of charges into the channel 105 and the ejection of the charges from the channel 105 make it possible to control a magnetization state in the channel 105.

In addition, applying a positive voltage to the gate 106 makes it possible to retain magnetization information in the channel 105 where charges are injected. Two states are set for polarization in the gate 106 depending on polarity of a voltage applied to the gate 106. With a positive voltage applied to the gate 106, a magnetization direction is retained in the channel 105 where charges are injected. Hereinafter, charges are assumed to be electrons with negative polarity, but charges may be holes with positive polarity. In that case, when a device is operated, a gate voltage has inverted polarity with respect to the polarity in a device where charges are electrons.

The spintronic device serves as a multi-valued memory by reading out the existence of charges in the channel 105 and the magnetization state in the channel 105 where the charges are injected. For example, the magnetization state control and readout of the existence of charges are possible by a control line (not illustrated) that is electrostatically coupled to the channel 105.

### Second Embodiment

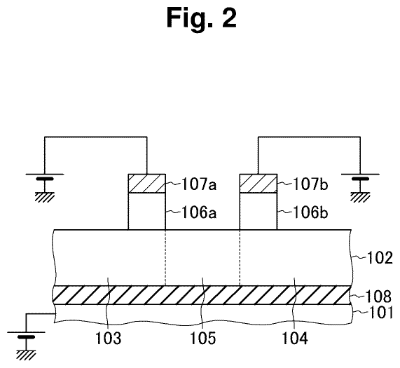

Next, a spintronic device according to a second embodiment of the present invention will be described with reference to FIG. 2. This spintronic device includes a semiconductor layer 102 formed on a substrate 101, a source 103 and a drain 104 formed in the semiconductor layer 102 at a predetermined interval, and a channel 105 formed between the source 103 and the drain 104 in the semiconductor layer 102. The channel 105 is a region in the semiconductor layer 102 doped with a magnetic impurity. Configurations of these components are similar to those described in the first embodiment.

In the second embodiment, the spintronic device includes a first ferroelectric layer 106a and a second ferroelectric layer 106b that are formed of a ferroelectric substance and apply an electric field to both ends of the channel 105 in a direction from the source 103 to the drain 104 to deplete the both ends of the channel 105. A first metallic electrode 107a is formed on the first ferroelectric layer 106a, and a second metallic electrode 107b is formed on the second ferroelectric layer 106b. The first ferroelectric layer 106a and the second ferroelectric layer 106b may be formed of, for example, HfO2.

For example, applying a positive voltage between the source 103 and the drain 104 enables injection of charges into the channel 105. In addition, adjusting a potential of the channel 105 by a voltage applied to the substrate 101 enables induction of the charges in the channel 105.

Furthermore, applying a positive voltage between the source 103 and the drain 104 and adjusting a potential of the channel 105 by a voltage applied to the substrate 101 enables ejection of the charges from the channel 105 to the drain 104. Still further, adjusting a potential of the channel 105 by a voltage applied to the substrate 101 enables elimination of the charges in the channel 105.

In the channel 105 where charges exist, interactions between the charges and impurity generates spontaneous magnetization in a direction opposite to charge spins. As described above, controlling the injection of charges into the channel 105 and the ejection of the charges from the channel 105 make it possible to control a magnetization state in the channel 105.

In the second embodiment, two states are set for polarization in each of the first ferroelectric layer 106a and the second ferroelectric layer 106b depending on polarity of a voltage applied to the first ferroelectric layer 106a and the second ferroelectric layer 106b. This polarization state is retained even when the application of a voltage is stopped due to spontaneous polarization of the ferroelectric substance. The spontaneous polarization in the first ferroelectric layer 106a and the second ferroelectric layer 106b depletes the semiconductor layer 102 immediately below the first ferroelectric layer 106a and immediately below the second ferroelectric layer 106b. Accordingly, the channel 105 is sandwiched between depleted regions, and the charges injected into the channel 105 are confined.

As described above, according to the second embodiment, without applying an electrical signal, it is possible to constantly accumulate charges in the channel 105, retain magnetization information in the channel 105, and impart the device with nonvolatile magnetization.

Unlike a multiferroic material, a ferromagnetic semiconductor formed by doping a semiconductor layer with a magnetic impurity is incredibly easy to manufacture. However, magnetization of a ferromagnetic semiconductor is eliminated by the influence of charge transfer or recombination due to external disturbance. Therefore, a technique that enables accommodation and accumulation of charges is important to utilize a ferromagnetic semiconductor as a recording device that retains magnetization information.

For example, in order to make a nonvolatile logic circuit with a ferromagnetic semiconductor, it is necessary to retain a charge accumulation or depletion state at any place and to record magnetization information while an input of an external electric field is blocked. However, in a single ferromagnetic semiconductor (particularly, in a fine structure), not only a surface or interface potential strongly affects internal charges but also ejection of charges is caused by heat, and it is difficult to conduct the aforementioned operations for the logic circuit.

In order to solve such problems, according to the second embodiment, the first ferroelectric layer 106a and the second ferroelectric layer 106b formed of a ferroelectric substance are used, and an electric field is applied to both ends of the channel 105 by spontaneous polarization of the ferroelectric substance to deplete the both ends of the channel 105, thereby achieving accommodation and accumulation of charges in the channel 105.

### Third Embodiment

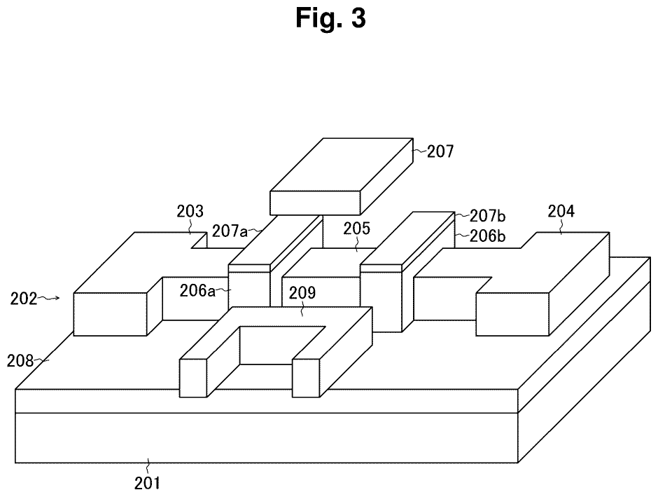

Next, a spintronic device according to a third embodiment of the present invention will be described with reference to FIG. 3. This spintronic device includes a semiconductor layer 202 formed on a substrate 201, a source 203 and a drain 204 formed in the semiconductor layer 202 at a predetermined interval, and a channel 205 formed between the source 203 and the drain 204 in the semiconductor layer 202. The channel 205 is a region in the semiconductor layer 202 doped with a magnetic impurity.

This spintronic device also includes a first ferroelectric layer 206a and a second ferroelectric layer 206b that are formed of a ferroelectric substance and apply an electric field to both ends of the channel 205 in a direction from the source 203 to the drain 204 to deplete the both ends of the channel 205. A first metallic electrode 207a is formed on the first ferroelectric layer 206a, and a second metallic electrode 207b is formed on the second ferroelectric layer 206b. Configurations of these components are similar to those described in the second embodiment.

In the third embodiment, a gate electrode 207 for applying an electric field to the channel 205 is disposed in a region between the first ferroelectric layer 206a and the second ferroelectric layer 206b. The spintronic device also includes a control line 209 electrostatically coupled to the channel 205 to control a magnetization state of the channel 205 and to read out the magnetization state of the channel 205. The control line 209 is disposed close to the channel 205 to an extent that enables electrostatic coupling to the channel 205. The control line 209 is formed of, for example, metal such as aluminum.

The substrate 201 is, for example, a silicon substrate. In this case, the semiconductor layer 202 is formed on the substrate 201 with an insulating layer 208 involved. The semiconductor layer 202 is formed of, for example, silicon. Examples of the magnetic impurity added to the semiconductor layer 202 in the region of the channel 205 includes Fe, Co, and Mn. The channel 205 doped with the magnetic impurity becomes a ferromagnetic semiconductor. The substrate 201 formed of silicon serves as a back gate.

In the spintronic device, the source 203, the drain 204, the gate electrode 207, and the substrate 201 serving as a back gate play a role in injecting charges (electrons or holes) into the channel 205. The injected charges play a role in confining charges in the channel 205 between the first ferroelectric layer 206a and the second ferroelectric layer 206b by depleting the semiconductor layer 202 immediately below the first ferroelectric layer 206a and the second ferroelectric layer 206b by electric fields applied from the first ferroelectric layer 206a and the second ferroelectric layer 206b.

In addition, the first ferroelectric layer 206a and the second ferroelectric layer 206b dynamically change a potential of the semiconductor layer 202 immediately below the first ferroelectric layer 206a and the second ferroelectric layer 206b, thereby injecting charges into the channel 205 and manipulating the charge injection rate and timing into the channel 205. The source 203, the gate electrode 207, and the substrate 201 modulate the energy level and carrier density in the channel 205. The substrate 201 is also used when information of the channel 205 on the substrate 201 is refreshed all at once. The control line 209 plays a role as a write electrode for controlling a magnetization direction recorded in the channel 205 and a role as a readout electrode for detecting charges accumulated in the channel 205.

This spintronic device has the following two features. Firstly, a ferromagnetic state is generated and controlled by induction of charges in the channel 205 that is made into a ferromagnetic semiconductor by doping a semiconductor with a magnetic impurity. Accordingly, the spintronic device is imparted with the capability to electrically induce and eliminate magnetization.

Secondly, the first ferroelectric layer 206a and the second ferroelectric layer 206b are formed of a ferroelectric substance. Even when inputs to the first ferroelectric layer 206a and the second ferroelectric layer 206b are blocked due to spontaneous polarization of the ferroelectric substance, charges are steadily accumulated in the channel 205, and it is possible to retain magnetization information in the channel 205 composed of a ferromagnetic semiconductor. In other words, the spintronic device is imparted with nonvolatile magnetization. In this manner, with the first ferroelectric layer 206a and the second ferroelectric layer 206b, it is possible to handle a ferromagnetic semiconductor as a multiferroic material.

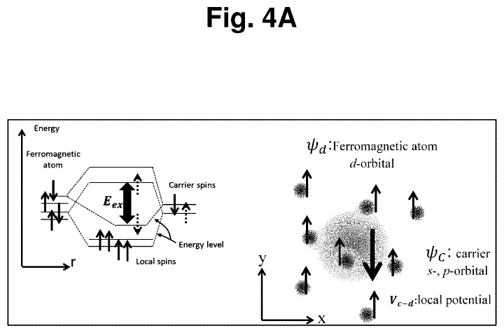

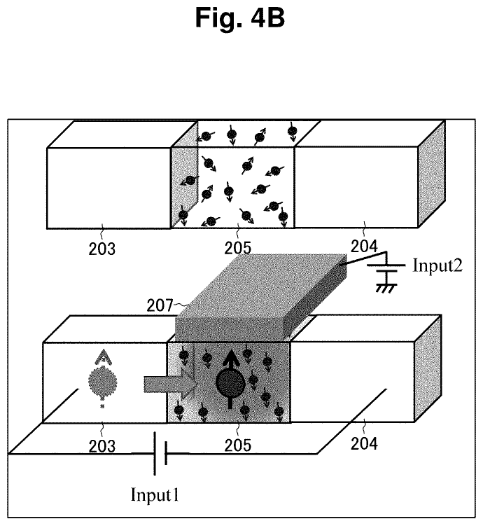

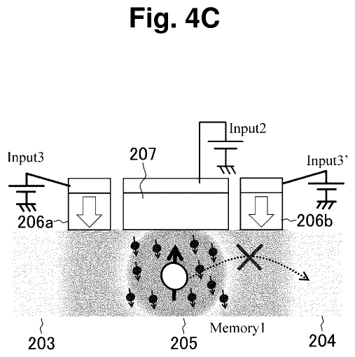

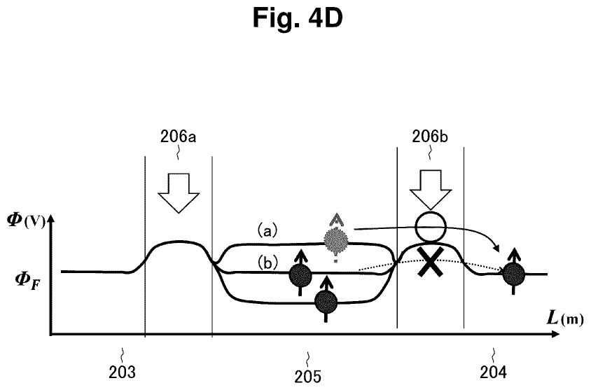

Hereinafter described are operations of the spintronic device. In a semiconductor doped with a magnetic impurity, as illustrated in FIG. 4A, interactions between charges and impurity ions generate charge spins indicated by downward arrows and spontaneous magnetization in a direction opposite to the charge spins (Reference Literature 1, Reference Literature 2, and Reference Literature 3). Upward arrows indicate impurity spins. In this spintronic device, the channel 205 is doped with the magnetic impurity, and as illustrated in FIG. 4B, charges are injected and ejected (Input 1) from the source 203 into the channel 205 to control a ferromagnetic state and a non-magnetic state. In addition, adjusting a potential of the channel 205 by applying a voltage between the gate electrode 207 and the substrate 201 enables generation and elimination of charges in the channel 205 (Input 2) and, similarly, generation and elimination of magnetism in the channel 205.

Furthermore, since an exchange interaction is a function of charge energy (Reference Literature 3), it is possible to modulate exchange interactions by controlling the charge density in the channel 205. Specifically, the charge density is modulated by controlling a potential by the gate electrode 207 and the substrate 201 and controlling confinement of carriers in the channel 205 by electric fields applied from the first ferroelectric layer 206a and the second ferroelectric layer 206b.

In order to accumulate the charges injected into the channel 205 after Input 1 and to manipulate an electric field by applying a voltage to the gate electrode 207 and the substrate 201, it is necessary to apply an electric field to the first ferroelectric layer 206a and the second ferroelectric layer 206b (Input 3) and insulate the channel 205 from the source 203 and the drain 204. FIG. 4C illustrates a state where a potential of a semiconductor channel immediately below the first ferroelectric layer 206a and the second ferroelectric layer 206b increases due to spontaneous polarization of the first ferroelectric layer 206a and the second ferroelectric layer 206b and the charges injected into the channel 205 are trapped. At this time, potentials of the entire device become as illustrated in FIG. 4D.

Even after Input 3 is stopped, charges are continuously accumulated in the channel 205 by the spontaneous polarization of the first ferroelectric layer 206a and the second ferroelectric layer 206b. In other words, magnetization information in the channel 205 is stored (Memory 1). On the other hand, even when the channel 205 is insulated, ejection and accumulation of charges are controllable by gate electric field control (Input 2) of the gate electrode 207 and the substrate 201 as in the potentials indicated by lines (a) and (b) in FIG. 4D. Since the first ferroelectric layer 206a and the second ferroelectric layer 206b are disposed on the left side (closer to the source 203) and the right side (closer to the drain 204) of the channel 205, operations to apply an electric field to these layers are separately defined as Input 3 (first ferroelectric layer 206a) and Input 3′ (second ferroelectric layer 206b). Such operations correspond to electrical generation of magnetization and retainment of the magnetization.

Next, a magnetization direction of Memory 1 is electrically controlled. This operation is achieved by a flow of current through the control line 209. The flow of current through the control line 209 generates a magnetic field. For example, mainly in a straight portion of the control line 209 facing the channel 205, a magnetic field generated by the right-handed screw rule penetrates the channel 205 in a thickness direction in response to polarity of the current. Due to the magnetic field penetrating this channel 205, the magnetization in the channel 205 is oriented in the direction of the applied magnetic field (thickness direction). It is also possible to continuously change the direction of the magnetic field of the magnetization in the channel 205 in response to changes in intensity or waveform of the current input to the control line 209 (analog signal processing). This operation is referred to as Input 4, and the magnetization direction is referred to as Memory 1.

For example, assuming that a direction perpendicular to a substrate plane is determined as a reference for the magnetization to be read out, Memory 1 uses, as information, not only states where the magnetization is oriented in a lateral direction (a direction of the plane of the substrate 201), upward direction, and downward direction but also a state without magnetization and states where the magnetization is inclined from three axes (x-axis, y-axis, and z-axis). Note that x-axis represents the gate length direction, y-axis represents the gate width direction, and z-axis represents the thickness direction. As described above, a ferromagnetic semiconductor obtained by doping a semiconductor with a magnetic impurity has a high degree of freedom in magnetization direction as compared with a multiferroic material in which a magnetization direction is uniquely determined in response to a polarization direction.

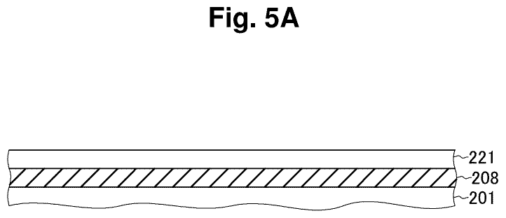

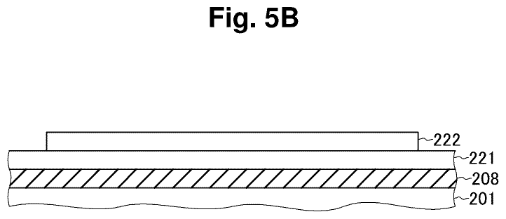

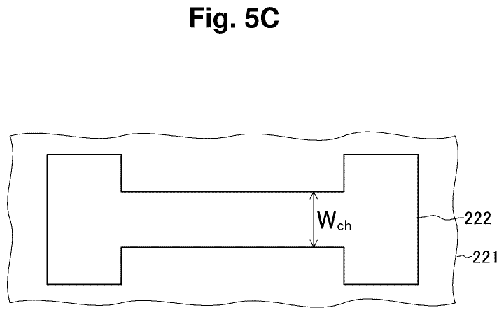

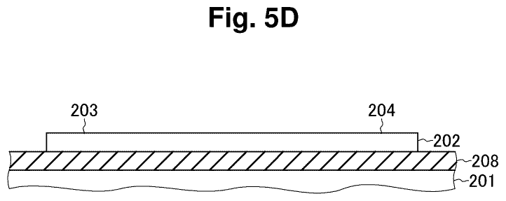

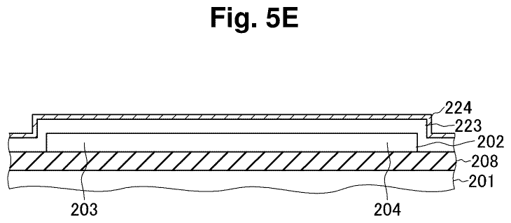

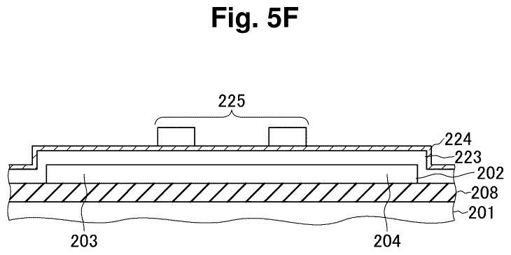

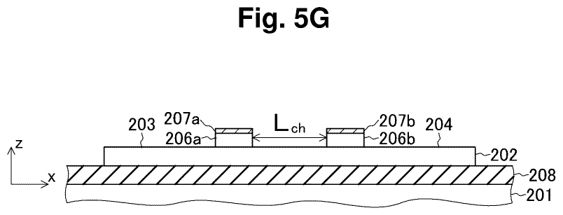

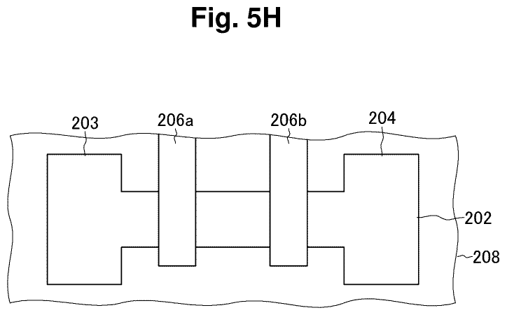

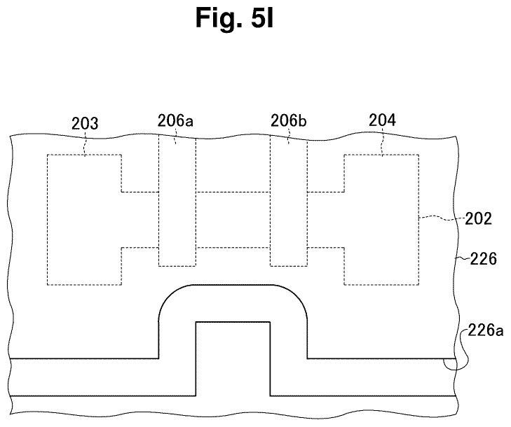

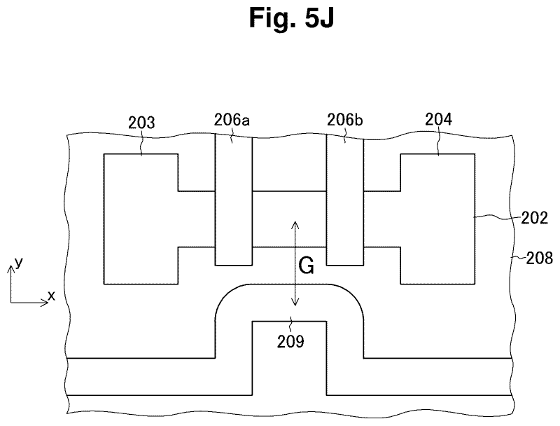

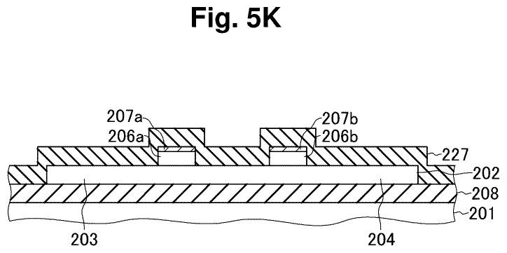

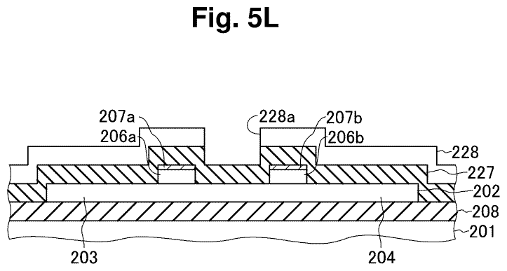

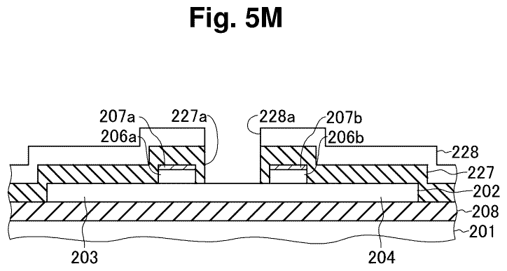

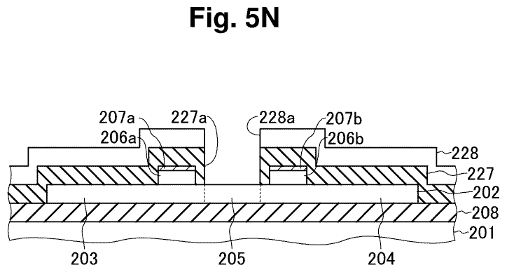

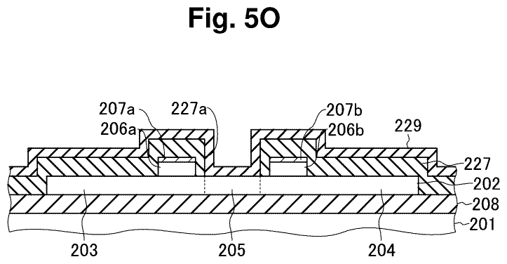

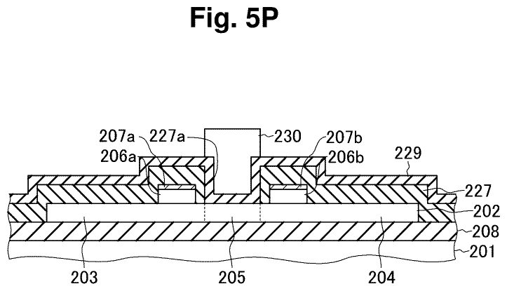

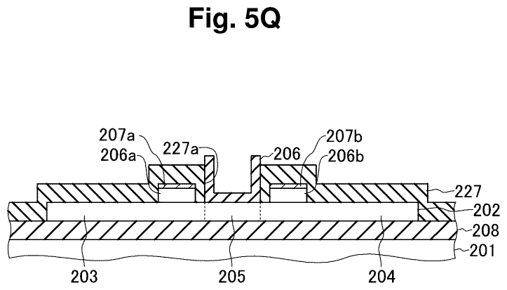

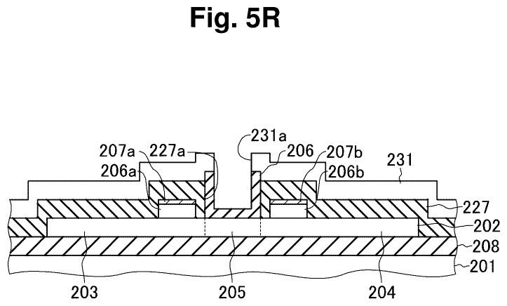

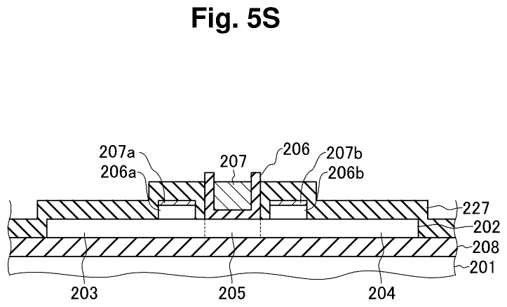

Next, a method for manufacturing the spintronic device according to the third embodiment will be described with reference to FIGS. 5A to 5S. This spintronic device is feasible by an existing technique of manufacturing a semiconductor device. Note that the following numerical values are examples and that the present invention is not limited thereto. Various values may be taken based on a combination of materials, an amount of magnetic impurity to be added, and the like.

First, as illustrated in FIG. 5A, a semiconductor layer 221 is formed on the substrate 201 formed of silicon with the insulating layer 208 involved. Since the substrate 201 is used as a back gate, the insulating layer 208 is formed on the substrate 201 in order to prevent charges from moving in the thickness direction of the device. The insulating layer 208 is formed of, for example, a silicon oxide. Furthermore, the semiconductor layer 221 is formed of, for example, silicon. The semiconductor layer 221 is formed to have a thickness of, for example, about 20 nm. The semiconductor layer 221 is used for forming the source 203, the drain 204, and the channel 205 and has a thickness equal to or less than a thickness to be depleted by electric fields applied from the first ferroelectric layer 206a and the second ferroelectric layer 206b.

Next, as illustrated in FIGS. 5B and 5C, a mask pattern 222 is formed on the semiconductor layer 221. The mask pattern 222 has a pattern for shaping the source 203, the drain 204, and the channel 205 in plan view. For example, a photosensitive resist is patterned by a known lithography technique.

Next, the semiconductor layer 221 is etched using the mask pattern 222 as a mask, followed by removing the mask pattern 222 to form the semiconductor layer 202 including regions that are to be the source 203 and the drain 204 as illustrated in FIG. 5D. A region of the semiconductor layer 202 sandwiched between the source 203 and the drain 204 (a region to be the channel 205) has, for example, a width Wch of about 20 nm in the gate width direction in plan view. The strength of a magnetic field applied from the control line 209 and the strength of electrostatic coupling decay in inverse proportion to the first power of a distance between the control line 209 and the channel 205. For this reason, a width of the channel 205 in plan view is equal to or less than a length that can control a magnetization direction of the entire width of the channel 205.

Next, as illustrated in FIG. 5E, a ferroelectric film 223 is formed on the semiconductor layer 202, and a conductor film 224 is formed on the ferroelectric film 223. The ferroelectric film 223 is formed by depositing a ferroelectric substance, for example, by sputtering or atomic layer deposition, and subsequently, the conductor film 224 is formed by depositing a conductive material. The material for the ferroelectric film 223 is not limited, but HfO2 is particularly adequate. HfO2 is a binary material and is deposited by atomic layer deposition that enables covering of the entire surface of an intricately shaped device (Reference Literature 4).

Next, as illustrated in FIG. 5F, a mask pattern 225 is formed on the conductor film 224. Next, the conductor film 224 and the ferroelectric film 223 are selectively etched in order using the mask pattern 225 as a mask, followed by removing the mask pattern 225 to form the first ferroelectric layer 206a and the second ferroelectric layer 206b as illustrated in FIGS. 5G and 5H. The first electrode 207a is formed on the first ferroelectric layer 206a, and the second electrode 207b is formed on the second ferroelectric layer 206b.

Formation of the first ferroelectric layer 206a and the second ferroelectric layer 206b determines a length Lch of the channel 205. The length Lch of the channel 205 is, for example, about 20 nm. In operating the spintronic device according to the third embodiment, the length Lch of the channel 205 is not limited. However, from viewpoints of ferromagnetic interactions, precise control of charge transport or accumulation, noise, and power consumption, the length Lch is shortened within a range that enables fine processing in order to reduce resistance of the entire device.

Next, the control line 209 is produced. As illustrated in FIG. 5I, the first step is to form a mask pattern 226 including an opening 226a in a region that is to be the control line 209. The mask pattern 226 is formed on the insulating layer 208, covering the semiconductor layer 202 (source 203, drain 204), the first ferroelectric layer 206a (first electrode 207a), and the second ferroelectric layer 206b (second electrode 207b).

The next step is to deposit metal used for the control line 209 on the mask pattern 226. The deposited metal film is formed on the mask pattern 226 and on the insulating layer 208 exposed through the opening 226a. After that, the mask pattern 226 is removed (lift off), leaving the metal film in the opening 226a, thereby forming the control line 209 as illustrated in FIG. 5J.

In order to enable electrostatic coupling between a magnetic field generated from the control line 209 and the channel 205, it is preferable to narrow an interval G between the channel 205 and the control line 209 to the extent possible. The gap is, for example, 40 nm.

Next, a magnetic impurity is injected into the semiconductor layer 202 between the source 203 and the drain 204 by ion implantation to make a ferromagnetic semiconductor, thereby forming the channel 205. As compared with other methods for depositing a ferromagnetic semiconductor, ion implantation has such an advantage that a desired position of an already formed semiconductor layer is locally made to have ferromagnetism.

As illustrated in FIG. 5K, the first step is to form an insulating layer 227 over the entire region of the device. As illustrated in FIG. 5L, the next step is to form a mask pattern 228 having an opening 228a in a region that is to be the channel 205 on the insulating layer 227. After that, as illustrated in FIG. 5M, the insulating layer 227 is selectively etched using the mask pattern 228 as a mask to form an opening 227a in the insulating layer 227 of the region that is to be the channel 205.

Next, a magnetic impurity is injected into the semiconductor layer 202 exposed through the opening 227a by ion implantation using the mask pattern 228 and the insulating layer 227 provided with the opening 227a as masks. For example, 1 at. % of Mn atoms are injected. After that, as illustrated in FIG. 5N, the impurity is activated by heat treatment to form the channel 205 in the semiconductor layer 202 between the source 203 and the drain 204. A maximum concentration of the magnetic impurity to be added is equal to a concentration (1 at. % for Si) that does not cause a heterogeneous phase like an intermetallic compound. Note that even in a metal or intermetallic compound cluster, magnetism is expected to be controlled by an electric field at a nanoscale level, and thus, the cluster can be selected as a part of a ferromagnetic semiconductor. The type of ions to be implanted is not limited as long as the ions enable a ferromagnetic semiconductor channel.

Next, after the mask pattern 228 is removed, an insulating film 229 is formed on the insulating layer 227 as illustrated in FIG. 5O. Next, as illustrated in FIG. 5P, a mask pattern 230 is formed on the insulating film 229, corresponding to the position of the opening 227a. Next, the insulating film 229 is etched using the mask pattern 230 as a mask, followed by removing the mask pattern 230 to form a gate insulating layer 206 on the channel 205 at the bottom of the opening 227a as illustrated in FIG. 5Q.

Next, a mask pattern 231 is formed on the insulating layer 227 (a part of the gate insulating layer 206) as illustrated in FIG. 5R. The mask pattern 231 includes an opening 231a at a portion where the gate electrode 207 is to be formed. Next, metal used for the gate electrode 207 is deposited on the mask pattern 231. The deposited metal film is formed on the mask pattern 231 and on the gate insulating layer 206 exposed through the opening 231a. After that, the mask pattern 231 is removed (lift off), leaving the metal film in the opening 231a, thereby forming the gate electrode 207 as illustrated in FIG. 5S. Note that the gate insulating layer 206 desirably has a layer structure that depletes the channel 205 at an interface where the gate insulating layer 206 comes in contact and has a high dielectric constant (HfO2/SiOx or the like).

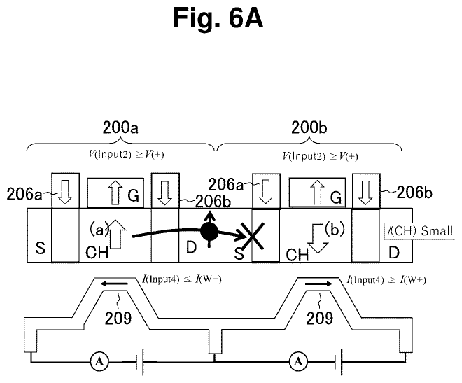

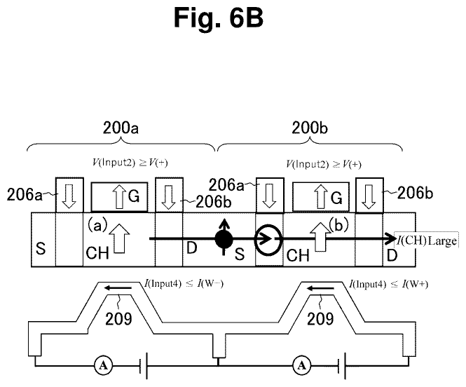

With reference to FIGS. 6A and 6B, hereinafter described are aspects in which the spintronic device according to the third embodiment is utilized as a nonvolatile multi-valued memory. In a structure employed in the following examples, the gate insulating layer 206 in the spintronic device is formed of a ferroelectric substance, and a spintronic device 200a and a spintronic device 200b are coupled to each other. The spintronic device 200a is used as a reference device, and the spintronic device 200b is used as a readout device. This configuration enables reading and writing of charges as well as magnetization simultaneously, thereby serving as a multi-valued memory. In FIGS. 6A and 6B, “S” represents the source 203, “D” represents the drain 204, “G” represents the gate insulating layer 206, and “CH” represents the channel 205.

First, readout of existence of magnetization and readout of a magnetization direction are detected by measuring series resistance of the entire device. When a current is applied to two joined ferromagnetic bodies, the series resistance (spin resistance) changes in proportion to the cosine of a relative angle between magnetization of one ferromagnetic body and magnetization of the other. This characteristic is applied to the magnetization of the device.

Specifically, a magnetization direction of CH in the spintronic device 200a serving as the reference device of the coupled spintronic device 200a and spintronic device 200b is predetermined by applying a current to the control line 209 (Input 4) [reference magnetization (a)]. A magnetic field generated by flowing a current through the control line 209 penetrates the channel 205, and the magnetization in the channel 205 is oriented in a direction of the applied magnetic field (thickness direction) (Input 4).

Readout magnetization (b) read out from CH of the spintronic device 200b serving as the readout device takes any direction by a signal (Input 4) applied to the control line 209 of the spintronic device 200b. In a case where the readout magnetization (b) is antiparallel to the reference magnetization (a) as illustrated in FIG. 6A, flowing a current from S of the spintronic device 200a to D of the spintronic device 200b maximizes the spin resistance. In other words, a current [I(CH)] of the channel 205 has a minimum value.

In contrast, in a case where the readout magnetization (b) is parallel to the reference magnetization (a) as illustrated in FIG. 6B, I(CH) has a maximum value. In a case where a relative angle of magnetization is right angle or one magnetization is turned off, the spin resistance eliminates and only polarization direction-dependent resistance in the channel 205 is read out by I(CH).

Polarization of the gate insulating layer 206 is read out by measuring resistance of the channel 205 or the control line 209. Since the channel 205 is a ferromagnetic semiconductor, the resistance of the channel 205 is changed by an electric field applied from the gate insulating layer 206 (gate electrode 207) (operation of a transistor).

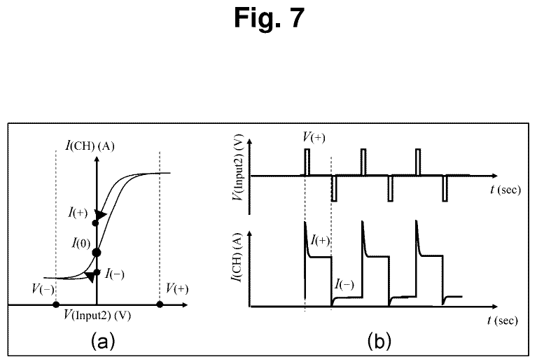

In FIG. 7, (a) illustrates current characteristics [I(CH)] of the channel 205 when an electric field, or Input 2, is swept from the gate insulating layer 206 (gate electrode 207) that has spontaneous polarization. When Input 2 is turned off after Input 2 is swept from V=0 to the positive side (V(+)) and to the negative side (V(−)), polarization of the positive and negative polarity is retained by the gate insulating layer 206. This corresponds to a state where positive and negative gate electric fields opposite to each other are applied, and a difference between I(+) and I(−) is caused in I(CH) at V=0. In other words, since the resistance changes depending on the polarization retained in the gate insulating layer 206, a polarization direction is read out by the operation of the transistor.

The polarization direction in the gate insulating layer 206 is defined as Memory 2. For example, when Input 2 is swept as illustrated in (b) of FIG. 7, I(CH) is stabilized at two values, I(+) and I (−), and the signal changes depending on polarity inversion (polarization rotation) of Input 2.

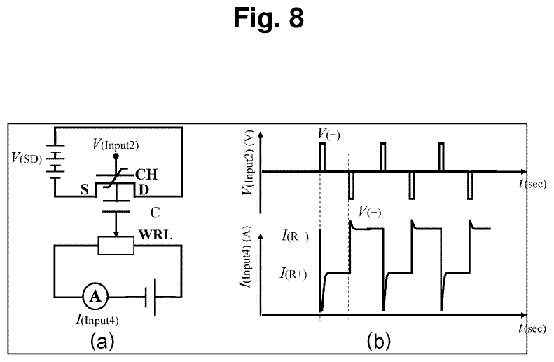

The channel 205 and the control line 209 are sufficiently close together and electrostatically coupled to each other. In FIG. 8, (a) illustrates an equivalent circuit diagram in which the channel 205 and the control line 209 are coupled by stray capacitance (C). When charges are accumulated in the channel (CH) 205, a potential of the WRL (control line 209) changes via the capacitance C. This potential change causes a resistance change in the control line 209 in proportion to charge density in the channel 205. Therefore, when a constant voltage is applied to the circuit of the control line 209, it is possible to read out the charge density in the channel 205 by measuring a current I(WRL) of the control line 209.

The corresponding polarization direction (Memory 2) is read from the read charge density. This technique is mainly applied to a case where the channel 205 is completely insulated from the source 203 and the drain 204 by Input 3 of the first ferroelectric layer 206a and the second ferroelectric layer 206b. For example, when Input 2 is swept as illustrated in (b) of FIG. 8, the current I(WRL) flowing through the control line 209 is stabilized at two values, I(R−) and I(R+), and the signal changes depending on polarity inversion (polarization rotation) of Input 2.

In this manner, Memory 2 by Input 2 and Memory 1 by Input 4 are read out. The following Table 1 shows the relationship between these combinations and I(CH). For simplicity, the reference magnetization is fixed to the upward direction. I(CH) takes five values, I(++↑↑), I(++↑↓), I(++), I(+−), and I(−−), based on a combination of a polarization state of the first ferroelectric layer 206a (TG1) and the second ferroelectric layer 206b (TG2) and a state of the readout magnetization. Since the relative angle of magnetization in the channel 205 takes a continuous value independent of the polarization direction, a continuous analog signal of I(CH) is expressed as I (++↑cosθ). θ is a relative angle between the reference magnetization and the readout magnetization. Combinations that take the value 0 in “Magnetization-dependent Resistance (Spin Resistance)” indicate conditions that cause no spin resistance.

TABLE 1

| Memory 2 | | Memory 1 (Input 4) | | Polarization- | Magnetization- | |
|---|---|---|---|---|---|---|
| (Input 2) | | Reference | Readout | dependent | dependent Resistance | |
| TG1 | TG2 | Magnetization | Magnetization | Resistance | (Spin Resistance) | I(CH) |
| + | + | ↑ | ↑ | R(++) | R(↑↑) | I(++↑↑) |
| + | − | | | R(+−) | 0 | I(+−) |
| − | − | | | R(−−) | 0 | I(−−) |
| + | + | ↑ | ↓ | R(++) | R(↑↓) | I(++↑↓) |
| + | − | | | R(+−) | 0 | I(+−) |
| − | − | | | R(−−) | 0 | I(−−) |
| + | + | ↑ | →(0 = 90°) | R(++) | 0 | I(++) |
| + | − | | | R(+−) | 0 | I(+−) |
| − | − | | | R(−−) | 0 | I(−−) |
| + | + | ↑ | ↑cosθ | R(++) | Rcos(θ(Input 4)) | I(++↑↑cosθ) |

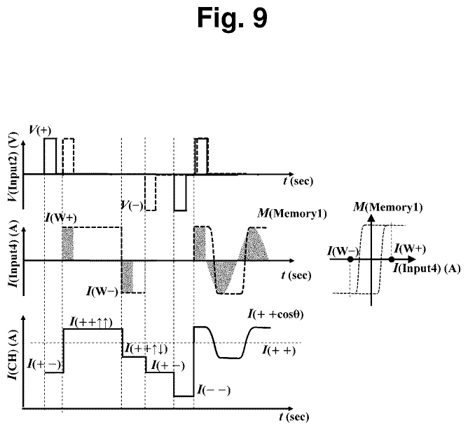

FIG. 9 illustrates an operational state of the multi-valued memory in which a plurality of states of outputs [J(CH)], that is, functions of Input 2 and Input 4, is retained even when inputs to the first ferroelectric layer 206a and the second ferroelectric layer 206b are blocked.

Even in the spintronic device according to the first embodiment, magnetization in the channel 105 is generated and controlled with a control line after injecting (inducing) charges into the channel 105. Furthermore, in the spintronic device according to the first embodiment, magnetization information is retained by applying V(+) to the gate 106 (electrode 107), but there are two options for polarization in the gate 106 depending on polarity of an applied voltage. Therefore, in a state where a voltage to be applied is positive (+), two or continuous magnetization directions are retained in the channel 105. Still further, in the spintronic device according to the first embodiment, similarly to the description with reference to FIGS. 6A and 6B, connecting two spintronic devices provided with control lines enables the spintronic devices to serve as a multi-valued memory.

With regard to the spintronic device according to the second embodiment, a polarization state of the first ferroelectric layer 106a and the second ferroelectric layer 106b corresponds to Memory 2 of the spintronic device according to the third embodiment. The polarization state of the first ferroelectric layer 106a and the second ferroelectric layer 106b is selected depending on polarity of an applied voltage. In a state where a voltage to be applied is V(+) (magnetization generation state), charges are accumulated in the channel 105, which generates magnetization. By controlling a magnetization state with a control line, two directions, that is, upward and downward directions, or continuous directions are given to the magnetization state in the channel 105. Even in the spintronic device according to the second embodiment, similarly to the description with reference to FIGS. 6A and 6B, connecting two spintronic devices provided with control lines enables the spintronic devices to serve as a multi-valued memory.

The spintronic device according to the first embodiment and the spintronic device according to the second embodiment are simpler than the structure of the spintronic device according to the third embodiment, which simplifies the device production process.

Furthermore, in the spintronic device according to the second embodiment, a magnetization direction is controllable by irradiating the channel 105 with circularly polarized light (Reference Literature 5). For example, when the surface of the channel 105 is irradiated with clockwise circularly polarized light from a vertical direction, a magnetization direction of charges injected (induced) into the channel 105 is directed upward. Conversely, when the surface of the channel 105 is irradiated with counterclockwise circularly polarized light from the vertical direction, the magnetization direction of the charges injected (induced) into the channel 105 is directed downward.

Since a channel obtained by doping a semiconductor layer with a magnetic impurity is regarded as a cell of a ferromagnetic memory, it is possible to apply a method for writing and reading out magnetization with a magnetic head. In this case, a control line is not required, which enables a further integrated device. For such operations, an adequate structure is that of the spintronic device according to the second embodiment which does not use a gate.

On the other hand, in the spintronic device according to the third embodiment, flowing a current enables the gate electrode 207, the first electrode 207a, and the second electrode 207b to substitute for the control line 209 that is responsible for Input 4. For example, in the gate electrode 207, since the gate insulating layer 206 is thinned to about 10 nm, an interval between the gate electrode 207 to be used as a control line and the channel 205 can be decreased further. Therefore, the magnetization in the channel 205 is controllable with smaller Input 4. This also indicates controllability of higher density magnetization.

Next, a width and a thickness of the channel in plan view are made into nanosize to such an extent that develops quantum effects and an interval between the two ferroelectric layers arranged by sandwiching the channel is made into nanosize, thereby strengthening the effect of confining charges in the channel.

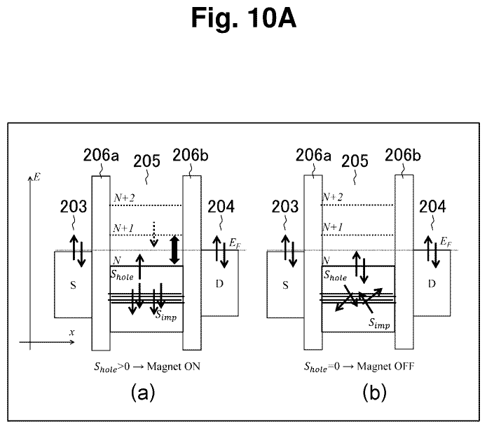

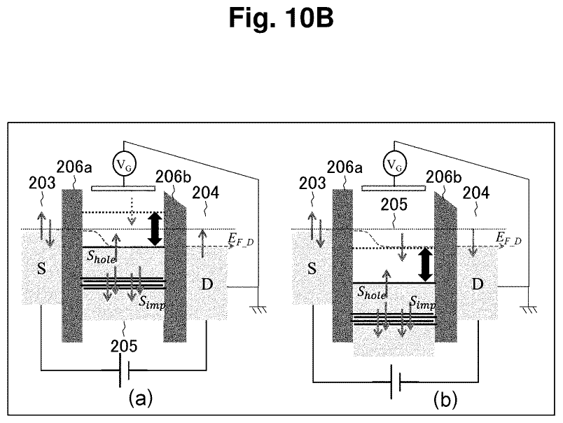

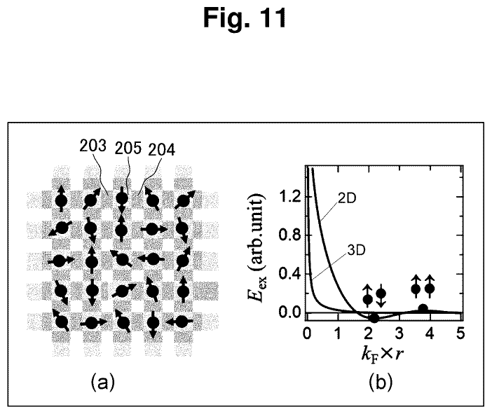

The nanoscale dimension of the channel 205 and the nanoscale interval between the first ferroelectric layer 206a and the second ferroelectric layer 206b cause a discretized electronic state in the channel 205 as illustrated in FIG. 10 A. Since a voltage required for the charge injection into the channel 205 is discretized, the value of I(CH) is discretized. In other words, a possible value of I(CH) is multi-valued. In FIG. 10A, downward arrows indicate charge spins, and upward arrows indicate impurity spins.

In a case where a charge state of the channel 205 is quantized, a spin state of the charges in the channel 205 becomes a single spin or a singlet state depending on even or odd numbers of charges. In this state, the number of spins of the channel 205 is finite [(a) in FIG. 10A] or 0 [(b) in FIG. 10A]. Since the number of spins and exchange interactions are proportional to each other, generation and elimination of magnetization (Memory 1) caused by the exchange interactions are controllable by even and odd numbers of charges. In other words, in a state where Input 2 at V(+) is applied to the gate electrode 207, an option not to generate magnetization is added to the states shown in Table 1.

As described above, in a case where the state in the channel 205 is discretized due to the nanoscale dimension and the exchange interactions cause a state of a ferromagnetic semiconductor with a finite value, spins of charges to be injected and accumulated from the source 203 into the channel 205 are oriented in a fixed single direction. For example, as illustrated in (a) of FIG. 10B, in a case where the energy level [Ech(N,↑)] in the channel 205 is made lower than the level of the source 203 and higher than the Fermi level (μF_D) of the drain 204 by Input 2, a state of charges transported from the source 203 to the channel 205 is limited to the state of charges in the channel 205 (the number of electrons N·upward spin), and only charges spinning upward are transported.

Conversely, as illustrated in (b) of FIG. 10B, in a case where the energy level of the source 203 is made higher than the virtual level [Ech(N+1,↓)] in the channel 205 and EF_D is made lower than Ech(N+1,↓), only charges spinning downward are transported. This phenomenon is referred to as spin filtering or spin blocking and is utilized as the source for generating a spin-polarized current.

A spin filter achieved by this spintronic device has a capability of controlling (ON/OFF) without an external magnetic field. Furthermore, the intensity of exchange interactions which is to be a drive force ranges up to 40 meV, and this energy scale corresponds to a temperature of 200° C. and a magnetic field of 340 T. In terms of operation without a magnetic field and thermal disturbance resistance, the spin filter has an advantage in device application as compared with a magnetic field-induced spin filter in the related art which uses semiconductor quantum dots.

Connecting the spintronic device with another spintronic device causes spin resistance similar to one described with reference to FIGS. 6A and 6B. This configuration enables the spintronic device to operate as a memory. Furthermore, for the aforementioned reasons, the spintronic device operates by transporting a single charge, that is, a minimum current.

The spintronic device according to embodiments of the present invention is also applicable to devices other than a memory. For example, as illustrated in (a) of FIG. 11, a plurality of spintronic devices may be connected in a lattice shape. Around charge spins inside the channel 205 of a ferromagnetic semiconductor, there are spin states that spread out while oscillating (Friedel oscillations) (Reference Literature 2). As illustrated by arrows in (a) of FIG. 11 that indicate charge spins, the oscillations as exchange interactions change depending on a distance and Fermi wavenumber.

In this manner, even in a configuration having a plurality of spintronic devices connected in a lattice shape, values of exchange interactions between adjacent channels 205 are controllable from positive to negative by controlling the distance between the adjacent channels 205 and the Fermi wavenumber. In this control, as illustrated in (b) of FIG. 11, magnetization of the adjacent channels 205 is stabilized in parallel or antiparallel or with a certain relative angle (Reference Literature 6). Note that, in (b) of FIG. 11, “2D” represents a value of a two-dimensional channel, and “3D” represents a value of a three-dimensional channel.

Since this phenomenon is described by the Ising model due to exchange interactions via charge spins, this lattice structure operates as an Ising machine. The Fermi wavenumber is controlled by an electric field generated by the first ferroelectric layer, the second ferroelectric layer, or the substrate (back gate). When the channels 205 are insulated from each other by electric fields from the first ferroelectric layer and the second ferroelectric layer, magnetization remains as it is, but there is no magnetic interactions between the channels 205.

In this state, when magnetic interactions in the channels 205 are weakened by an electric field from the gate electrode or the substrate, the magnetization starts to rotate randomly due to thermal disturbance. Exchange interactions between the channels 205 are generated again by operations of the first ferroelectric layer and the second ferroelectric layer. Repeating the operations at high speed corresponds to annealing of the magnetization. When the charge spins are released from the channels 205 by applying a predetermined voltage to the source 203, the substrate, and the gate electrode, magnetization information of each channel 205 eliminates, thereby initializing information of the spintronic devices.

The arrangement of the plurality of spintronic devices is freely selected from square lattice, hexagonal lattice, and kagome lattice. If the channels 205 are regarded as pseudo magnetic atoms, it is possible to simulate the relationship between magnetization behavior and exchange interactions in a lattice of various magnetic atoms.

As described above, according to embodiments of the present invention, a ferroelectric layer is disposed on a channel formed by adding a magnetic impurity between a source and a drain in a semiconductor layer, thereby enabling a new spintronic device that uses a ferromagnetic semiconductor. A spintronic device that combines a ferromagnetic semiconductor and a ferroelectric layer enables a charge-magnetization multivalued memory that can be manufactured by a semiconductor device manufacturing process in the related art without using a ferromagnetic metal film. In addition, such a spintronic device enables electrical generation, control, and retainment of magnetization and serves as a general-purpose memory device having characteristics of a transistor and a hard disk.

In the above description, silicon is employed as a semiconductor included in a ferromagnetic semiconductor serving as a channel and Fe, Co, or Mn is employed as a magnetic impurity to be added, but the present invention is not limited to this example. Embodiments of the present invention can employ a ferromagnetic body obtained by any combination of a semiconductor and a magnetic impurity that enables a ferromagnetic semiconductor. Furthermore, a material included in a first ferroelectric layer, a second ferroelectric layer, and a gate is not limited to HfO2, and the present invention can employ any ferroelectric substance.

Note that the present invention is not limited to the embodiments, and it is clear that various modifications and combinations can be implemented by those skilled in the art without departing from the technical spirit of the present invention.

### Reference Literature

Reference Literature 1—M. A. Ruderman and C. Kittel, “Indirect Exchange Coupling of Nuclear Magnetic Moments by Conduction Electrons”, Physical Review, vol. 96, no. 1, pp. 99-102, 1954.
Reference Literature 2—T. Kasuya, “A Theory of Metallic Ferro- and Antiferromagnetism on Zener&apos;s Model”, Progress of Theoretical Physics, vol. 16, no. 1, pp. 45-57, 1956.
Reference Literature 3—K. Yosida, “Magnetic Properties of Cu—Mn Alloys”, Physical Review, vol. 106, no. 5, pp. 893-898, 1957.
Reference Literature 4—T. S. Boscke et al., “Ferroelectricity in hafnium oxide thin films”, Applied Physics Letters, vol. 99, 102903, 2011.
Reference Literature 5—R. C. Myers et al., “Zero-field optical manipulation of magnetic ions in semiconductors”, Nature Materials, vol. 7, pp. 203-208, 2008.
Reference Literature 6—H. Tamura et al., “Tunable Exchange Interaction in Quantum Dot Devices”, Japanese Journal of Applied Physics, vol. 43, no. 5B, pp. L691-L693, 2004.

### REFERENCE SIGNS LIST

101 Substrate
102 Semiconductor layer
103 Source
104 Drain
106 Gate
106a First ferroelectric layer
106b Second ferroelectric layer
107a First electrode
107b Second electrode
108 Insulating layer

1-4. (canceled)

5. A spintronic device comprising:
a semiconductor layer disposed on a substrate;
a source and a drain in the semiconductor layer;
a channel between the source and the drain in the semiconductor layer and doped with a magnetic impurity; and
a first ferroelectric layer and a second ferroelectric layer that are formed of a ferroelectric substance, wherein the first ferroelectric layer and the second ferroelectric layer are collectively configured to apply an electric field at both ends of the channel in a direction from the source to the drain to deplete the both ends of the channel.

6. The spintronic device according to claim 5, further comprising
a gate electrode configured to apply an electric field to the channel in a region between the first ferroelectric layer and the second ferroelectric layer.

7. The spintronic device according claim 6, further comprising:
a control line that is electrostatically coupled to the channel, the control line being configured to control a magnetization state of the channel and to read out the magnetization state of the channel.

8. The spintronic device according to claim 5, wherein the magnetic impurity comprises Fe, Co, or Mn.

9. The spintronic device according claim 8, further comprising:
a control line that is electrostatically coupled to the channel, the control line being configured to control a magnetization state of the channel and to read out the magnetization state of the channel.

10. The spintronic device according claim 5, further comprising:
a control line that is electrostatically coupled to the channel, the control line being configured to control a magnetization state of the channel and to read out the magnetization state of the channel.

11. A spintronic device comprising:
a semiconductor layer disposed on a substrate;
a source and a drain in the semiconductor layer;
a channel between the source and the drain in the semiconductor layer and doped with a magnetic impurity; and
a gate that is formed of a ferroelectric substance and configured to apply an electric field to the channel.

12. The spintronic device according claim 11, further comprising:
a control line that is electrostatically coupled to the channel, the control line being configured to control a magnetization state of the channel and to read out the magnetization state of the channel.

13. The spintronic device according to claim 11, wherein the magnetic impurity comprises Fe, Co, or Mn.

14. The spintronic device according claim 13, further comprising:
a control line that is electrostatically coupled to the channel, the control line being configured to control a magnetization state of the channel and to read out the magnetization state of the channel.
